(19) United States
(12) Patent Application Publication
(10) Pub. No.: US 2022/0219125 A1
(43) Pub. Date: Jul. 14, 2022

(54) HYBRID INORGANIC OXIDE-CARBON MOLECULAR SIEVE MEMBRANES

(71) Applicant: King Abdullah University of Science and Technology, Thuwal (SA)

(72) Inventors: Ingo PINNAU, Thuwal (SA); Wojciech OGIEGLO, Thuwal (SA); Tiara PUSPASARI, Thuwal (SA)

(21) Appl. No.: 17/607,915

(22) PCT Filed: Apr. 29, 2020
(86) PCT No.: PCT/IB2020/054041

§ 371 Date: Nov. 1, 2021

Related U.S. Application Data
(60) Provisional application No. 62/924,765, filed on Oct. 23, 2019.
(60) Provisional application No. 62/841,479, filed on May 1, 2019.

(51) Int. Cl. B01D 71/02; B01D 67/00

(52) U.S. Cl. CPC B01D 71/021; B01D 53/228; B01D 71/024; B01D 67/0067

(57) ABSTRACT

Embodiments include methods of fabricating thin film composite carbon molecular sieve membranes by exposing a polymer layer to a vapor-phase metal-organic precursor under vapor phase infiltration conditions such that the vapor-phase metal- organic precursor diffuses into the polymer layer and reacts with a functional group of the polymer to form an inorganic-organic complex; exposing the polymer layer to a vapor-phase co-reactant under vapor phase infiltration conditions such that the vapor- phase co-reactant diffuses into the polymer layer and oxidizes the organic-inorganic complex to form a metal oxide; and subjecting the polymer layer to inert-atmosphere or vacuum pyrolysis. Embodiments further include thin film composite carbon molecular sieves, and methods of separating one or more chemical species using the carbon molecular sieve membranes.

### BACKGROUND

The pressing need to improve industrial energy efficiency is one of the key elements to facilitate the urgent transition of society towards a more sustainable economy. Separation processes account for a significant portion of the total industrial energy consumption as such processes still largely rely on energy-intensive thermally-driven unit operations, such as distillation, drying, or evaporation. In this context, membrane technology offers extremely attractive opportunities to reduce those energy demands by as much as 90%. This, however, requires development of not only new membrane materials (of which thousands have been studied), but also fabrication of highly productive membranes. In particular, in gas separations the latter is typically accomplished by selecting a promising membrane material and transforming it into a high-permeance thin film device in which a thin selective layer provides a high selectivity while a mechanically robust support delivers durability and low flow resistance. These properties allow membrane devices efficient realization of technologically important separation tasks—such as natural gas production, air separation or carbon capture—using only pressure differences, with virtually no heat input.

Currently available membrane materials, however, are often unable to combine all the necessary characteristics of an effective and durable membrane device. The minimum requirements of such membrane devices include attractive gas separation properties. Frequently, however, characteristics such as ease of thin film fabrication and upscaling, mechanical and chemical resistance, long-term stability, resistance to aging and plasticization (related with swelling induced by condensable gases, e.g. CO₂, hydrocarbons), among others, take on even greater importance. In this view, carbon molecular sieves (CMS) have long been considered an attractive alternative to both all-polymeric and ceramic membranes. CMS membranes are fabricated by a high temperature (400-1000° C.) treatment of a highly aromatic polymer precursor under essentially inert atmosphere. As a result of the pyrolytic collapse, a turbostratic, amorphous, and highly microporous (pores<20 Å) material is formed. The co-existance of ultramicropores (<7 Å) together with larger micropores provides exceptionally attractive gas separation properties (usually far above the capabilities of all-polymeric materials) with a very good chemical and plasticization resistance. At the same time, the use of an organic polymer precursor contributes to good scalability of CMS membranes by allowing the exploitation of well-established solution-based techniques.

Despite obvious advantages, CMS membranes possess several shortcomings, which they partly share with other microporous amorphous materials when fabricated into thin films in the thickness range of a few microns or less. One of the most detrimental ones is the physical aging, where the excess fractional free volume or microporosity is progressively lost due to a naturally-occurring densification of the structure. This process proceeds spontaneously, is accelerated in thin films, and leads to dramatic losses in gas permeability over timescales relevant in membrane processes (weeks to years). Despite its importance, physical aging in thin film CMS membranes has been very rarely reported in the literature. Various efforts have been undertaken to inhibit physical aging. Most notable ones include the polymer design, mixing with fillers, post modification or blending. Although effective in thick isotropic films to some extent, the practicability and effectiveness of those approaches in thin films remain challenging. Among the hurdles more typical to CMS thin film membranes, the major ones are related with the need for cost-effective, mechanically stable supports that would allow tapping into the particularly attractive selectivities of high temperature carbons (e.g., those pyrolyzed above 700° C.). This is usually achieved with relatively expensive ceramic supports. Alternatively, all polymeric hollow fiber precursors have been utilized which, however, require additional procedures to avoid support pore collapse.

### SUMMARY

The present invention relates to microporous thin film composite carbon molecular sieve membranes (TFC CMS membranes), methods of fabricating said membranes, methods of separating chemical species using said membranes, and the like.

In a first aspect, the present invention is directed to methods and/or processes of fabricating thin film composite carbon molecular sieve membranes. The methods can proceed by pyrolysis of a membrane modified by a vapor phase infiltration process. More specifically, the methods can proceed by (a) exposing a polymer layer to a vapor-phase metal-organic precursor under vapor phase infiltration conditions, wherein the vapor-phase metal-organic precursor diffuses into the polymer layer and reacts with a functional group of the polymer to form an inorganic-organic complex; (b) exposing the polymer layer to a vapor-phase co-reactant under vapor phase infiltration conditions, wherein the vapor-phase co-reactant diffuses into the polymer layer and oxidizes the organic-inorganic complex to form a metal oxide; and (c) subjecting the polymer layer to inert-atmosphere or vacuum pyrolysis.

In another aspect, the present invention is directed to thin film composite carbon molecular sieve membranes fabricated according to the methods and/or processes disclosed herein. The thin film composite carbon molecular sieve membranes can comprise a thin selective layer supported on a substrate. The thin selective layer can include an organic-inorganic hybrid material, the organic-inorganic hybrid material comprising a metal oxide molecularly dispersed throughout a microporous carbon matrix.

In a further aspect, the present invention is directed to methods in which the thin film composite carbon molecular sieve membranes are utilized to separate one or more chemical species. The methods can proceed by contacting the thin film composite carbon molecular sieve membranes disclosed herein with a fluid composition and separating at least one chemical species from the fluid composition. The fluid compositions can include chemical species selected from the group consisting of CO₂, CH₄, O₂, N₂, He and H₂, among others. In certain embodiments, the thin film composite carbon molecular sieve membranes can be utilized to separate CO₂ from CH₄. In certain embodiments, the thin film composite carbon molecular sieve membranes can be utilized to separate O₂ from N₂. In certain embodiments, the thin film composite carbon molecular sieve membranes can be utilized to separate H₂ from N₂. In certain embodiments, the thin film composite carbon molecular sieve membranes can be utilized to separate He from N₂

The details of one or more examples are set forth in the description below. Other features, objects, and advantages will be apparent from the description and from the claims.

### BRIEF DESCRIPTION OF DRAWINGS

This written disclosure describes illustrative embodiments that are non-limiting and non-exhaustive. In the drawings, which are not necessarily drawn to scale, like numerals describe substantially similar components throughout the several views. Like numerals having different letter suffixes represent different instances of substantially similar components. The drawings illustrate generally, by way of example, but not by way of limitation, various embodiments discussed in the present document.

Reference is made to illustrative embodiments that are depicted in the figures, in which:

FIG. 1A is a flowchart of a method of fabricating a thin film composite carbon molecular sieve membrane, according to one or more embodiments of the present disclosure.

FIG. 1B is a flowchart of a method of separating one or more chemical species, according to one or more embodiments of the present disclosure.

FIGS. 2A-2B show (A) a schematic drawing of the methods disclosed herein and (B) a graphical view of permeance, according to one or more embodiments of the present disclosure.

FIGS. 3A-3B show (A) a reaction scheme of the thin film composite carbon membrane fabrication based on a PIM-polyimide with incorporated vapor phase infiltration step, which can by repeated multiple times prior to pyrolysis, and application of the protective PDMS coating; and (B) a proposed chemical scheme showing the creation of the organic-inorganic complex around the carbonyl functional group of the pristine polymer followed by an oxidation reaction leading to a nano-dispersed Al₂O₃ within the PIM matrix, according to one or more embodiments of the present disclosure.

FIGS. 4A-4G are graphical views presenting (A)-(D) Secondary Ion Mass Spectroscopy (SIMS) data showing a graded infiltration of Al element from the surface up to about 150 nm depth into the PIM precursor film, the Al ion deposition is preserved upon high temperature treatment (pyrolysis); and (E)-(G) X-Ray Photoelectron Spectroscopy data including the survey spectra, as well as the O 1 s and Al 2 p peaks, indicating that Al₂O₃ is chemically intact and loosely (physically) bound within the PIM precursor as well as after the pyrolysis, according to one or more embodiments of the present disclosure.

FIGS. 5A-5H are graphical views presenting (A)-(B) membrane permeances as a function of the gas kinetic diameters showing an increasing molecular sieving ability with the increasing number of vapor infiltration cycles for samples pyrolyzed at 500 and 600° C.; (C)-(E) gas separation performance of the nano-hybrid thin film carbon membranes for CO₂/CH₄ and O₂/N₂ gas pairs (pure gas) plotted on a trade-off diagrams; and (F)-(H) physical aging trajectories for nano-hybrid CMS membranes pyrolyzed at 500 and 600° C., with the respective points correspond to aging times of: 1, 5, 11, 30, and 60 days going from the higher to lower permeabilities and for CO₂/CH₄ data, only up to 30 days is presented due to a very low CH₄ permeability (below detection limits), according to one or more embodiments of the present disclosure.

### DETAILED DESCRIPTION

Industrial separations rely on heat-consuming unit operations involving a phase change (e.g., distillation) and thus are some of the most energy-intensive technological processes. Membrane technology has been viewed as a promising candidate for reducing the high-energy demand of such separations, but progress has been limited due to an inability to obtain membranes that exhibit the requisite separation performance characteristics and chemical and mechanical stability. While carbon molecular sieves are an example of another membrane technology under consideration, reported carbon molecular sieves suffer from physical aging—where the excess fractional free volume or microporosity is progressively lost due to naturally-occurring densification of the structure (e.g., physical aging). In addition, conventional fabrication techniques are energy-intensive processes, requiring high temperatures to form membranes with requisite mechanical stability and selectivity required for industrial separations, and thus are difficult to scale-up to meet the demands of industry.

The present invention overcomes these and other challenges in the art. In particular, it has been discovered that vapor phase infiltration can be utilized to modify polymer materials and form, following pyrolysis, high-quality defect- and crack-free hybrid metal oxide-carbon molecular sieve membranes as thin film composite membranes. Advantageously, the metal oxides are dispersed on a molecular level (e.g., molecularly dispersed), allowing the formation of thin films, and the weight or volume fraction of the metal oxides can be controlled, permitting the microporosity of the resulting membrane to be modulated. In addition, the membranes of the present disclosure exhibit exceptional separation properties (e.g., strong sieving capabilities, etc.), typical of high-temperature commercial membranes, except the membranes disclosed herein can be fabricated at much lower temperatures (e.g., about 200° C. to 300° C. less). Further, the physical aging characteristics of the membranes disclosed herein show that membrane selectivity actually increases with time. The practical advantages of these and the other benefits disclosed herein are numerous: a wide array of previously-unsuitable supports can now be employed, the risk of mechanical damage due to thermal stress (e.g., pore collapse, cracking, etc.) is reduced, and a simple and less energy-intensive process can be used for manufacturing processes thereby lowering operating costs.

Embodiments therefore include methods of preparing thin film composite carbon molecular sieve membranes. The methods involve pyrolysis of a polymer layer modified by a vapor phase infiltration process. The vapor phase infiltration process can proceed by exposing a polymer layer to a vapor-phase metal-containing precursor under conditions that allow the metal-containing precursor to diffuse into the free volume polymer matrix of the polymer layer where it reacts with polymer functional groups residing therein to form an organic-inorganic complex. The polymer layer can be further exposed, either simultaneously or subsequently, to a vapor-phase co-reactant that selectively and locally oxidizes the organic-inorganic complex to form a metal oxide molecularly nano-dispersed throughout the polymer matrix. The steps of exposing the polymer layer to the vapor-phase metal-containing precursor and vapor-phase co-reactant can be performed one or more times to control or adjust the volume fraction of the metal oxide present within the polymer matrix of the polymer layer. Following vapor phase infiltration, the polymer layer can be subjected to pyrolysis, such as inert-atmosphere or vacuum pyrolysis, to form the TFC CMS membranes of the present disclosure.

The resulting thin film composite carbon molecular sieve membranes can comprise a thin selective layer supported on a substrate, the thin selective layer comprising a metal oxide dispersed throughout a microporous carbon matrix. The membranes disclosed herein exhibit excellent molecular separation properties positioned in the vicinity or above the polymeric state of the art for a number of technologically important gas pairs (e.g. CO₂/CH₄, O₂/N₂, and H₂/N₂). In addition, the membranes disclosed herein can achieve separation properties typical to high temperature carbons despite being formed at moderate pyrolysis temperatures. This could potentially simplify the choice of a suitable CMS membrane support for practical applications. Moreover, the physical aging characteristics of the obtained membranes are shown to be distinct from the typical rapid loss of permeance with largely preserved selectivity typical to un-doped CMS thin films. The VPI-derived nano-hybrid CMS membranes, in contrast, seem to gain selectivity with aging up to 2 months after fabrication. Given a very large spectrum of available metalorganic VPI precursors, as well as broad possibilities to optimize the doping process it is believed that the presented method shows a tremendous potential both for a precise fine-tuning of the membrane properties and for upscaling.

### Definitions

The terms recited below have been defined as described below. All other terms and phrases in this disclosure shall be construed according to their ordinary meaning as understood by one of skill in the art.

As used herein, the term “vapor phase infiltration” or “vapor phase infiltration process” describes processes in which vapor- or gas-phase metal-organic precursors diffuse into polymers and react with polymer functional groups and/or co-reactants. The product resulting from vapor phase infiltration is an organic-inorganic hybrid material comprising a metal-organic precursor distributed throughout a polymer matrix. The bulk diffusion and entrapment of metal-organic precursors in a polymer matrix differentiates vapor phase infiltration, which proceeds sub-surface, from atomic layer deposition, which involves the absorption of precursors to a substrate surface. Examples of vapor phase infiltration processes include, but are not limited to, multiple pulsed infiltration (MPI), sequential infiltration synthesis (SIS), and sequential vapor infiltration (SVI).

As used herein, the term “carbon membrane” or “carbon matrix” refers to a polymeric membrane or polymer matrix that has been heated beyond its decomposition temperature. Pyrolysis or carbonization are examples of techniques used for heating a material beyond its decomposition temperature.

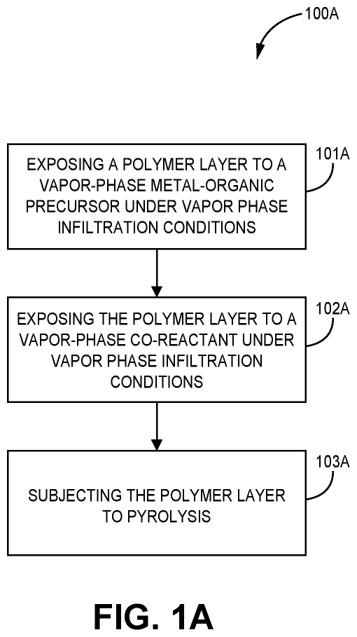

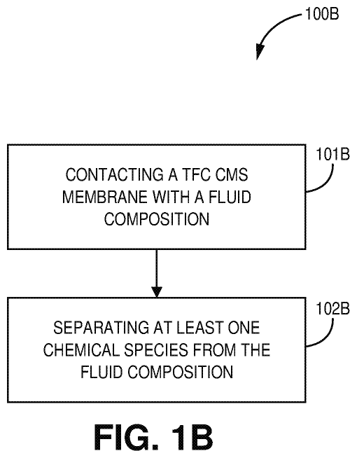

A flowchart of a method of fabricating a thin film composite carbon molecular sieve membrane is shown in FIG. 1A, according to one or more embodiments of the present disclosure. The method 100A can include vapor phase infiltration of a polymer film with a metal-organic precursor followed by oxidation and pyrolysis. For example, as shown, the method 100A can comprise exposing 101A a polymer layer to a vapor-phase metal-containing precursor under vapor phase infiltration conditions. Under such conditions (which are described in more detail below), the metal-organic precursor is allowed to diffuse into the polymer layer and react with the functional groups residing therein to form organic-inorganic complexes. The exposing can proceed in any reaction chamber or reaction vessel suitable for performing, or that has been adapted to perform, vapor phase infiltration and optionally pyrolysis. In certain embodiments, the reaction chamber is a chemical vapor deposition chamber, wherein the chemical vapor deposition chamber has been adapted for vapor phase infiltration. In certain embodiments, the reaction chamber is an atomic layer deposition chamber, wherein the atomic layer deposition chamber has been adapted for vapor phase infiltration. These are provided only as examples of suitable reaction chambers. Other reaction chambers known in the art can be employed herein without departing from the scope of the present invention.

The manner in which the exposing 101A is performed is not particularly limited. Examples of exposing include, but are not limited to, introducing, flowing, injecting, feeding, contacting, and pumping, among other techniques. The exposing can include a single deposition sequence or multiple deposition sequences, which can be continuous, static, semi-static, or pulsed. For example, in certain embodiments, the exposing proceeds by pulsing the vapor-phase metal-organic precursor into a reaction chamber that contains the polymer layer or polymeric precursor. The pulsing can proceed for a duration in the range of about 0.01 ms to about 100 ms, although other durations can be employed without departing from the scope of the present disclosure. An exposure period—e.g., contacting time of the metal-containing precursor with the polymer layer following the pulsing—can provide an opportunity to optimize the methods disclosed herein. In certain embodiments, the exposure period can be in the range of about 1 s to about 300 s and can follow the pulsing to facilitate and/or promote diffusion of the metal-organic precursor into the polymer layer. An example of a suitable exposure period is about 10 s, but other durations can be employed without departing from the scope of the present disclosure. For example, exposure periods can range from about 1 sec to about 72 h, or any increment thereof. Following the exposure period, the vapor-phase metal-containing precursor can optionally be purged from the reaction chamber.

The conditions under which the exposing 101A proceeds should be suitable for performing vapor phase infiltration. Parameters such as reactivity, polymer free volume, glass transition temperature of the polymeric precursor, decomposition temperature of the polymer, and reaction rate, among others, can inform the selection of the temperatures, pressures, etc. under which the vapor phase infiltration process is conducted. Suitable temperatures include temperatures in the range of about 25° C. to about 250° C., or any increment thereof. For example, in certain embodiments, the exposing proceeds at or to a temperature in the range of about 50° C. to about 150° C. In some embodiments, the exposing proceeds at or to a temperature that is below the glass transition temperature of the polymeric precursor. Suitable pressures include pressures in the range of about 1×10⁻⁶ mTorr to about 2 Torr, or any increment thereof. In certain embodiments, the exposing proceeds under a pressure of about 2 Torr. Other temperatures and pressures can be employed without departing from the scope of the present invention. Thus, in other embodiments, the temperatures can be less than 25° C. or greater than 250° C. and/or the pressures can be less than about 1×10⁻⁶ mTorr or greater than about 2 Torr.

The polymer layer can comprise a polymeric precursor selected to form a carbon molecular sieve membrane following vapor phase infiltration and/or pyrolysis. The polymeric precursor can be selected from polymers or other organic-based materials that form or are capable of forming free-standing or supported carbon molecular sieve membranes, including thin film composite carbon molecular sieve membranes. Suitable polymeric precursors include homopolymers, copolymers, multicomponent polymers, polymer blends, and the like. Preferred polymeric precursors will be microporous (e.g., pore size of less than or equal to 2 nm) and/or have characteristics of high aromatic carbon content, chemical and mechanical stability, and good film-forming and separation property, among others. The polymeric precursor can comprise or can be modified to comprise a functional group or side chain selected to react or complex with the metal-organic precursor. For example, in certain embodiments, the polymeric precursor comprises or can be modified to comprise any functional group including nitrogen, oxygen, phosphorus, sulfur, halogens (e.g., Br, Cl, I, etc.), or any combination thereof. Non-limiting examples of such functional groups include carbonyls, amines, hydroxyls, sulfonyls, cyano groups, or combinations thereof.

An example of an exemplary polymeric precursor is polymers of intrinsic microporosity (PIM), including polyimides of intrinsic microporosity (PIM-PIs). Any polymer of intrinsic microporosity, including polyimides of intrinsic microporosity, can be utilized herein. In general, PIMs are a class of intrinsically microporous polymers generally characterized as amorphous polymers having rigid and contorted backbones that prevent efficient packing of polymer chains. Their rigid and contorted backbones allow trapping of very high amounts of excess fractional free volume or microporosity. PIMs can also be characterized as having favorable (e.g., very high) aromatic carbon content. In certain embodiments, the polymer layer has a characteristic of being microporous and/or ultramicroporous, with a pore size or average pore size of about 2 nm or less. In certain embodiments, the polymer layer has a characteristic of having an aromatic carbon content in the range of about 65% to about 99%, or any increment thereof. For example, in certain embodiments, the polymer layer can have an aromatic carbon content of about 84%. In other embodiments, the aromatic carbon content can be less than about 65% or even about 100% or less.

In certain embodiments, the polymer layer comprises a PIM, wherein the PIM is a reaction product of one or more of the following:

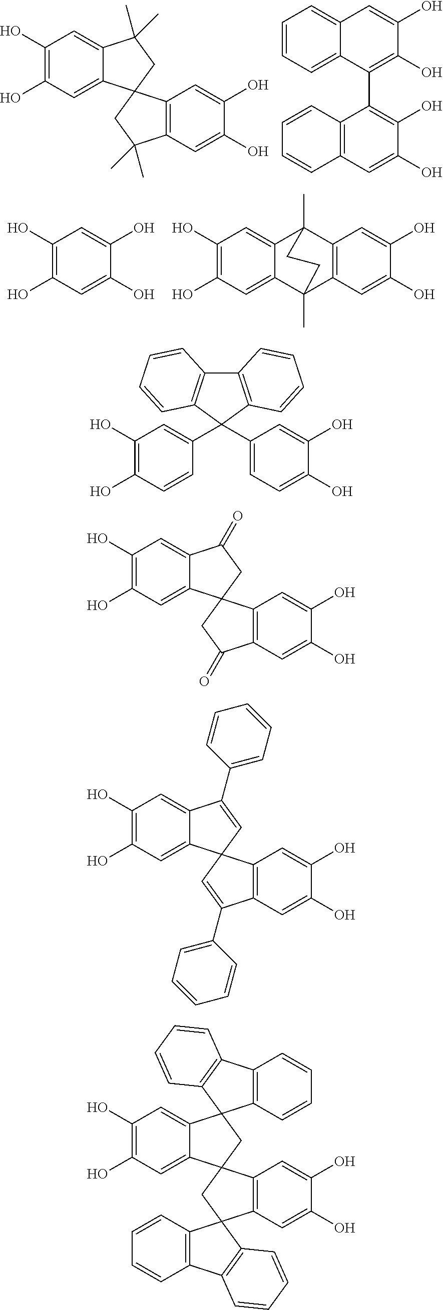

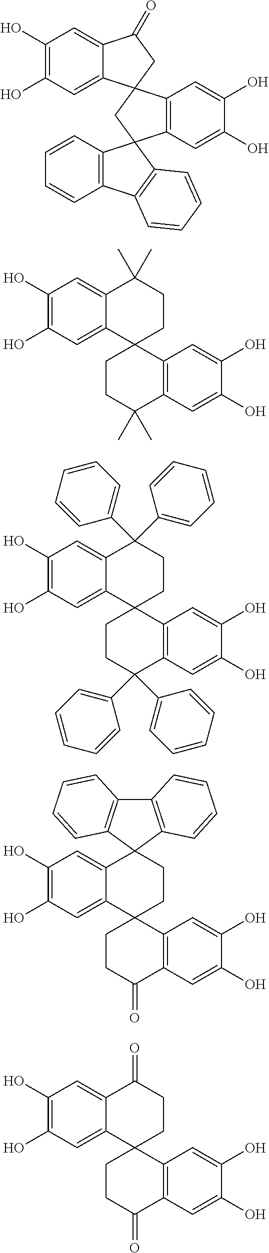

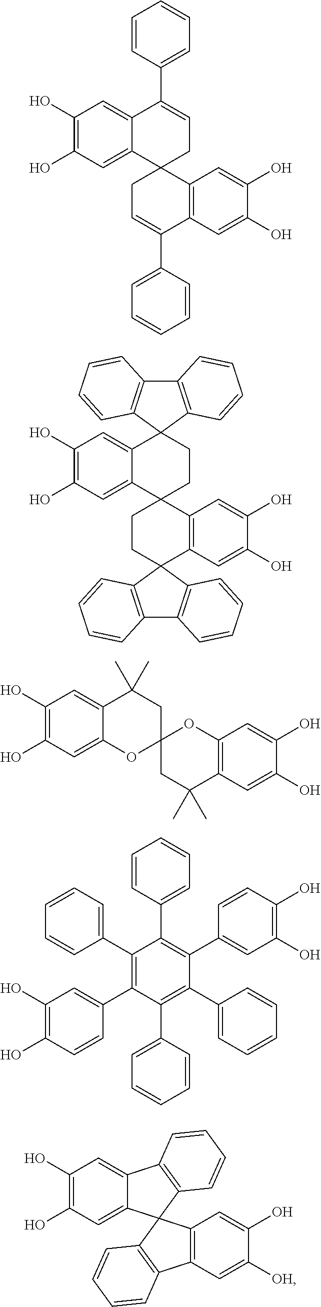

with one or more of the following:

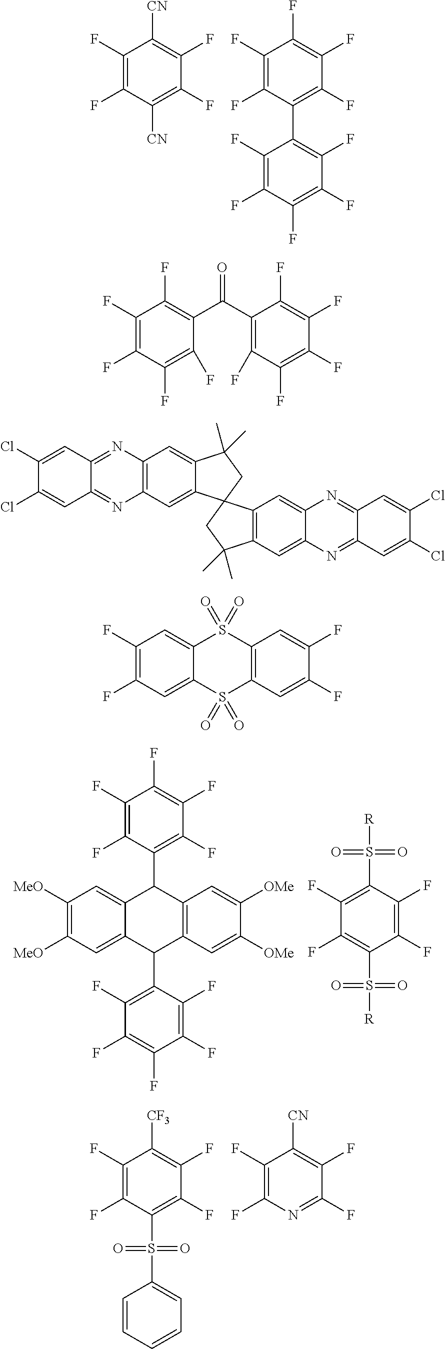

wherein each R is independently selected from: substituted and unsubstituted aryls such as phenyl; substituted and unsubstituted alkyls such as methyl, ethyl, propyl, butyl, pentyl, etc. Non-limiting examples of substituted aryls as R include:

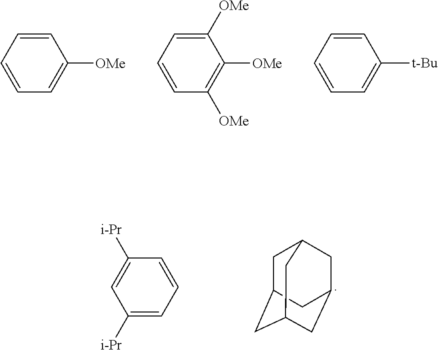 [SMILES: COc1ccccc1 ; COc1cccc(OC)c1OC ; CC(C)(C)c1ccccc1 ; CC(C)c1cccc(C(C)C)c1 ; C1C2CC3CC1CC(C2)C3]

In certain embodiments, the polymer layer comprises a PIM, wherein the PIM is a reaction product of one or more of the following:

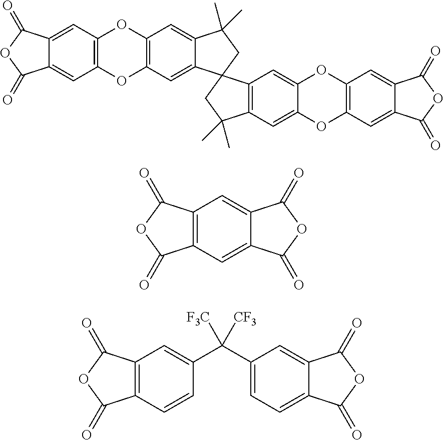 [SMILES: CC1(C)CC2(CC(C)(C)c3cc4oc5cc6c(=O)oc(=O)c6cc5oc4cc32)c2cc3oc4cc5c(=O)oc(=O)c5cc4oc3cc21 ; O=c1oc(=O)c2cc3c(=O)oc(=O)c3cc12 ; O=C1OC(=O)c2cc(C(c3ccc4c(c3)C(=O)OC4=O)(C(F)(F)F)C(F)(F)F)ccc21]

with one or more of the following:

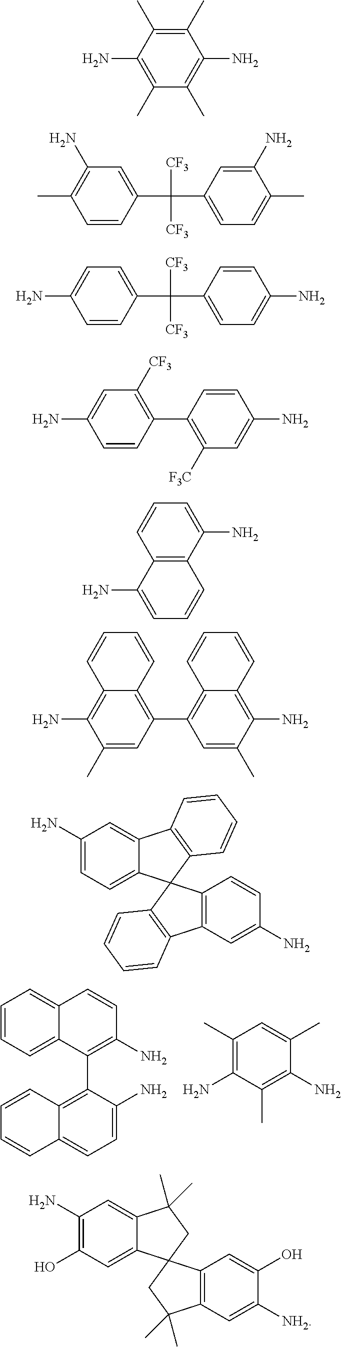

Non-limiting examples of suitable PIMs that can be utilized herein include SBFDA-DMN, EA-DMN, and EAD-DMN shown below:

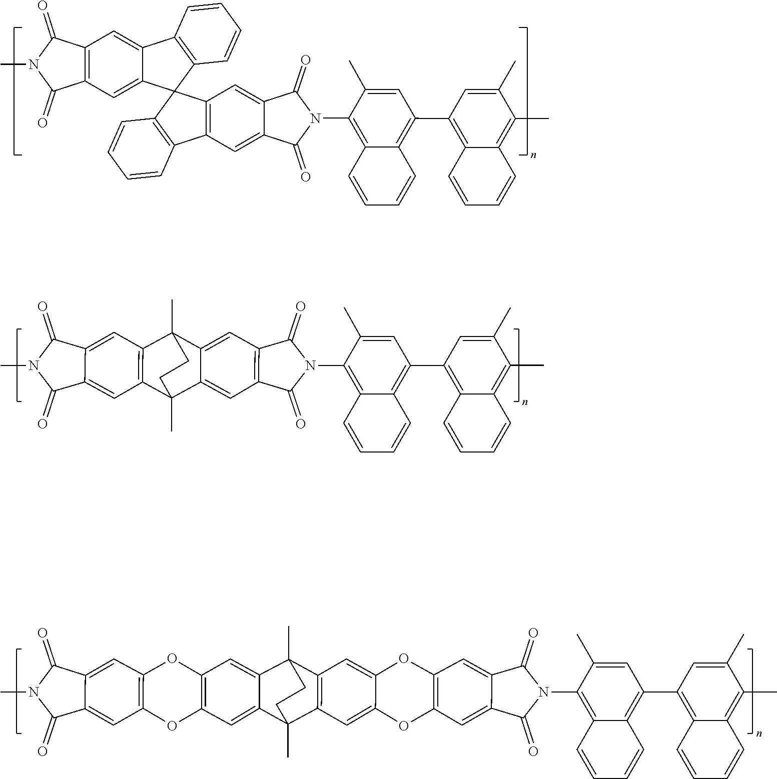

Additional examples of suitable PIMs that can be utilized herein include microporous polymers invented by Applicant. See, for example, those provided in WO2019012349A1, WO2019012347A1, U.S. Pat. No. 9,751,985B2, U.S. Pat. No. 9,944,751B2, WO2017221135A1, WO2017060863A1, WO2017212382A1, WO2017195068A1, WO2015001422A2, and continuing applications therefrom.

In addition to PIMs, other suitable polymeric precursors include, but are not limited to, polyimides, polyetherimides, polyphenylene oxide, (trimethylsilyl)-substituted polyphenylene oxide, poly(furfuryl alcohol), phenolic resin, sulfonated phenolic resin, phenol formaldehyde resin (PFR), polypyrrolone, poly(phthalazinone ether sulfone ketone), polyacrylonitrile (PAN), poly(vinylidene chloride-co-vinyl chloride), polyaniline, halopolymers such as fluoropolymers among others, cellulose, poly(benzimidazole) blended with polyimide, polypropylene oxide blended with polyvinylpyrrolidone, polyacrylonitrile blended with polyethylene glycol, polyethylene, polypropylene, polybutylene, polyvinylidine fluoride (PVDF), polyvinylflouride (PVF), polychlorotetrafluoroethylene (PCTFE), polytetrafluoroethylene (PTFE) and expanded PTFE, polyamides, polyalkylenes, poly(phenylenediamine terephthalamide) filaments, modified cellulose derivatives, starch, polyesters, polymethacrylates, polyacrylates, polyvinyl alcohol, copolymers of vinyl alcohol with ethylenically unsaturated monomers, polyvinyl acetate, poly(alkylene oxides), vinyl chloride homopolymers and copolymers, terpolymers of ethylene with carbon monoxide and with an acrylic acid ester or vinyl monomer, polysiloxanes, polyfluoroalkylenes, poly(fluoroalkyl vinyl ethers), homopolymers and copolymers of halodioxoles and substituted dioxoles, derivatives thereof, combinations thereof, and the like. Examples of other suitable polymer precursors include, but are not limited to, polysulfones; poly(styrenes), including styrene-containing copolymers such as acrylonitrilestyrene copolymers, styrene-butadiene copolymers and styrene-vinylbenzylhalide copolymers: polycarbonates; cellulosic polymers, such as cellulose acetate-butyrate, cellulose propionate, ethyl cellulose, methyl cellulose, nitrocellulose, etc.; poly-amides and polyimides, including aryl polyamides and aryl polyimides; polyethers; polyetherimides; polyetherketones; poly(arylene oxides) such as poly(phenylene oxide) and poly(xylene oxide); poly(esteramide-diisocyanate); polyurethanes; polyesters (including polyarylates), such as poly(ethylene terephthalate), poly(alkyl methacrylates), poly(acrylates), poly(phenylene terephthalate), etc.; polypyrrolones; polysulfides; polymers from monomers having alpha-olefinic unsaturation other than mentioned above such as poly(ethylene), poly(propylene), poly(butene-1), poly(4-methyl pentene-1), polyvinyls, e.g., poly(vinyl chloride), poly(vinyl fluoride), poly(vinylidene chloride), poly(vinylidene fluoride), poly(vinyl alcohol), poly(vinyl esters) such as poly(vinyl acetate) and poly(vinyl propionate), poly(vinyl pyridines), poly(vinyl pyrrolidones), poly(vinyl ethers), poly(vinyl ketones), poly(vinyl aldehydes) such as poly(vinyl formal) and poly(vinyl butyral), poly(vinyl amides), poly(vinyl amines), poly(vinyl urethanes), poly(vinyl ureas), poly(vinyl phosphates), and poly(vinyl sulfates); polyallyls; poly(benzobenzimidazole); polyhydrazides; polyoxadiazoles; polytriazoles; poly(benzimidazole); polycarbodiimides; polyphosphazines; etc., and interpolymers, including block interpolymers containing repeating units from the above such as terpolymers of acrylonitrile-vinyl bromide-sodium salt of para-sulfophenylmethallyl ethers; and grafts and blends containing any of the foregoing. Typical substituents providing substituted polymers include halogens such as fluorine, chlorine and bromine; hydroxyl groups; lower alkyl groups; lower alkoxy groups; monocyclic aryl; lower acyl groups and the like.

The polymer layer can optionally be supported on a substrate. The substrate or support is preferably porous, but in some instances, the substrate can be non-porous. In certain embodiments, the substrate is a heat sensitive substrate. As used herein, a heat sensitive substrate includes a material that degrades at temperatures of about 600° C. or higher, such as about 700° C. Degrading can include thermal chemical decomposition, cracking, pore collapse, formation of defects, among others. Examples of suitable supports include, but are not limited to, anodisc alumina membrane (AAO), carbon foam, ceramic membranes, or polymeric membranes such as membranes formed from polycarbonate, polyvinylidene fluoride, polysulfone, polyacrylonitrile, polyethersulfone, poly(ether sulfone ketone), poly(ether ethyl ketone), poly(phthalazinone ether sulfone ketone), polypropylene, cellulose acetate, cellulose diacetate, cellulose triacetate, polytetrafluoroethylene, polyamide, porous ceramic hollow fibers or tubes, porous metal hollow fibers or tubes, gamma-alumina coated porous alumina discs, tubes and hollow fibers, mixtures thereof, or copolymers thereof.

The metal-containing precursor can be selected from metals capable of existing in a gas- or vapor-phase. In addition or in the alternative, the metal-containing precursor should be capable of forming a complex with a functional group of the polymeric precursor, capable of being oxidized by the co-reactant, and/or capable of diffusing into the polymer layer. In certain embodiments, the metal-containing precursor forms a reversible complex with the functional group of the polymeric precursor. Examples of suitable metal-containing precursors include, but are not limited to, metal-organic precursors (e.g., metal alkyls, metal alkoxides, metal carboxylates such as metal acetates, metal complexes, and the like), metal-halide precursors, and the like. The metal-containing precursors can include transition metals, post-transition metals, lanthanoids, actinoids, alkali metals, or alkaline earth metals, or any combination thereof. In certain embodiments, the metal is selected from the group consisting of Al, Zn, Cd, S, Se, Ti, Zr, W, or Pd (among other heavy metal atoms). Preferred metal-containing precursors are metal-organic precursors such as trimethylaluminum, diethyl zinc, and titanium tetrachloride. Other non-limiting examples of suitable metal-containing precursors include triethylaluminum, titanium isopropoxide, zinc oxide, zinc chloride, zirconium tetrachloride, titanium oxide, aluminum trichloride, tungsten hexafluoride, silane, molybdenum fluoride, tetraethylorthosilicate, dimethylchloro aluminum, methyldichloro aluminum, and other metal alkyls, metal tetrakisalkylamidos, metal cyclopentadienyls, and metal diketonates. These shall not be limiting as other metal-containing precursors can be used herein without departing from the scope of the present disclosure.

In some embodiments, the functional groups within the polymer layer can react or complex with metal-organic precursors to afford organic-inorganic complexes. Given that the metal-organic precursors are allowed to diffuse into the polymer layer (e.g., below the polymer layer surface), the organic-inorganic complexes are typically, but not exclusively or necessarily, sub-surface. In addition, the spatial arrangement of the organic-inorganic complexes throughout the polymeric matrix of the polymer layer can depend on any of a variety of factors, including the vapor phase infiltration conditions, distribution and accessibility of reactive functional groups, number of vapor phase infiltration cycles performed, and polymer packing, among other things. Preferably, the organic-inorganic complexes are about uniformly or evenly dispersed throughout or within the polymeric matrix.

The polymer layer or polymeric precursor can be simultaneously or subsequently further exposed to one or more vapor-phase co-reactants in step 102A. Under such conditions (and like the metal-containing precursor discussed above), the co-reactant can diffuse into the polymer matrix of the polymer layer and react with (e.g., oxidize) the organic-inorganic complex to form metal oxides. The metal oxide(s) formed can have the formula: MₓO_{y}, where M is a metal from the metal-containing precursor or the organic-inorganic complex, O is an oxygen atom, x and y are each at least 1. Non-limiting examples of metal oxides include Al₂O₃, ZnO, and TiO₂, among numerous others. The exposure of the polymer layer or polymeric precursor to the vapor-phase co-reactant can proceed in the same or similar manner to the exposing described above in connection with step 101A, and thus is not repeated here. The co-reactant can be selected from any material suitable for oxidizing the organic-inorganic complexes by the vapor phase infiltration processes disclosed herein. Preferably, oxygen sources are utilized as the co-reactant. In certain embodiments, the co-reactant is capable of or selected to selectively or locally oxidize the organic-inorganic complex, or preferably selected to selectively and locally oxidize the organic-inorganic complex. Examples of suitable co-reactants include, but are not limited to, O₂, H₂O, H₂O₂, O₃, aluminum alkoxides, and the like, or preferably water vapor.

The steps of exposing the polymer layer to the vapor-phase metal-containing precursor in step 101A and the vapor-phase co-reactant in step 102A can constitute one cycle of a vapor phase infiltration process. In general, one or more cycles of the vapor phase infiltration process can be performed to tune, control, and/or adjust the volume fraction of metal oxide(s), among other things, within the polymeric precursor. As the number of cycles of vapor phase infiltration performed increases, the molecular sieving performance of the membranes described herein can observe further enhancement through an improvement or tightening of microporosity. In general, the number of vapor phase infiltration cycles performed is not particularly limited. For example, the number of vapor phase infiltration cycles performed can be at least one vapor phase infiltration cycle. In certain embodiments, 2 or more vapor phase infiltration cycles can be performed, such as 5 vapor phase infiltration cycles can be performed, 10 vapor phase infiltration cycles can be performed, 20 vapor phase infiltration cycles can be performed, or any increment thereof. In some embodiments, more than 20 vapor phase infiltration cycles are performed.

The diffusion of the metal-organic precursor and/or co-reactant can be characterized by a penetration depth, or the depth to which either or both of the metal-containing precursor and/or co-reactant diffuse below the surface. The penetration depth can also be used to characterize the depth of the organic-inorganic complex and/or metal-oxides. As noted above, usually the metal-containing precursor and/or co-reactant diffuse below a surface of the polymer layer, although in some instances either or both can exist, preferably in sparing amounts, on a surface. The penetration depths that can be attained can increase with increasing free volume of the polymer layer or polymeric precursor. In certain embodiments, the penetration depth can be confirmed by secondary ion mass spectroscopy, among other techniques. For example, a metal ion signal as determined by spectroscopy can be utilized to indicate or determine the penetration depth and can optionally be about constant even following pyrolysis (discussed below). The penetration depth can be dependent on the thickness of the polymer layer. In general, the penetration depth can be in the range of surface level depth (e.g., on the surface of the polymer layer) to the interface between the polymer layer and a support, if present, preferably with an about uniform or even distribution throughout the entire polymer layer. In certain embodiments, the penetration depth can be characterized as a percentage of the entire thickness of the polymer layer in the range of about 1% to about 100%, where a penetration depth of 100% indicates that, for example, a metal oxide is detected at a distance from the surface of the polymer layer that is about the same as the thickness of the polymer layer (e.g., at the polymer layer-substrate interface). In some embodiments, the penetration depth is about 150 nm.

Upon completing the desired number of vapor phase infiltration cycles, the polymer layer or polymer precursor can be subjected to pyrolysis in step 103A to form the thin film composite carbon molecular sieve membrane. The pyrolysis can include inert-atmosphere pyrolysis or vacuum pyrolysis, among other forms of pyrolysis. A person of ordinary skill in the art will readily recognize and appreciate other suitable forms of pyrolysis, which can be utilized herein without departing from the scope of the present disclosure. Advantageously, the pyrolysis of the polymer layer can proceed at temperatures that are lower than the pyrolysis temperatures required by conventional methods. Conventional methods, for example, typically require temperatures that are greater than about 700° C. and are frequently even greater than about 800° C., whereas pyrolysis of the polymer layer can be achieved according to the methods disclosed herein at temperatures as low as 500° C. or less. Accordingly, the pyrolysis temperature is not particularly limited and can include any temperature in the range of about 200° C. or greater, or any increment thereof. In certain embodiments, the pyrolysis can proceed at or to temperatures in the range of about 800° C. or less, preferably in the range of about 700° C. or less, or any increment or value thereof. In certain embodiments, the pyrolysis can proceed at or to temperatures in the range of about 500° C. to about 1000° C., about 500° C. to about 900° C., about 500° C. to about 800° C., about 500° C. to about 700° C., about 500° C. to about 650° C., about 500° C. to about 600° C., about 550° C. to about 700° C., about 550° C. to about 690° C., about 550° C. to about 650° C., about 400° C. to about 900° C., about 400° C. to about 800° C., about 400° C. to about 700° C., about 400° C. to about 650° C., about 400° C. to about 600° C., about 400° C. to about 550° C., or any increment or value thereof.

The metal and/or metal oxides remain within the structure following pyrolysis. This can be confirmed, for example, using Secondary Ion Mass Spectroscopy, among other techniques. In some embodiments, the metal oxide is present in molecular form, for example, throughout the carbon matrix. In some embodiments, the metal oxide is bound or loosely (e.g., physically) bound to the polymer chains. The weight fraction of the metal oxide within the structure can vary. In some embodiments, the weight fraction of the metal oxide present within the structure prior to pyrolysis (e.g., in the polymer layer) is about the same or substantially the same as the weight fraction thereof following pyrolysis (e.g., present in the carbon matrix). The weight fraction can depend on the number of vapor phase infiltration cycles performed, among other factors. In general, the weight fraction can be in the range of about 0.01% or greater.

A protective layer can optionally be deposited on the thin film composite carbon molecular sieve membrane in optional step 104A. The protective layer is not particularly limited and can include organic materials or inorganic materials, or combinations thereof, preferably organic materials such as polymers. In certain embodiments, the protective layer is a thin film of PDMS, which can be deposited onto the surface of the membrane according to known techniques, which are thus not particularly limited.

### THIN FILM COMPOSITE CARBON MOLECULAR SIEVE MEMBRANES

Thin film composite carbon molecular sieve membranes fabricated according to the methods of the present disclosure are also disclosed herein. In some embodiments, nano-hybrid thin film composite carbon molecular sieve membranes are provided that comprise a thin selective layer comprising a metal oxide dispersed or nano-dispersed throughout a carbon matrix. For example, in some embodiments, the thin selective layer comprises molecular metal oxides dispersed throughout the carbon matrix. The thin selective layer can optionally be supported on a substrate. In addition or in the alternative, a protective layer can optionally be deposited on a surface of the thin selective layer. The metal oxides, thin selective layer, supports and/or substrates, and protective layers can comprise or be derived/prepared from any of the components previously described, including without limitation, the polymers and polymer layers, metal-containing precursors and metals thereof, co-reactants, and so on.

The nano-hybrid TFC CMS membranes can be characterized as microporous, ultramicroporous, or both. For example, in some embodiments, the average pore size of the thin selective layer of the nano-hybrid TFC CMS membranes is in the range of about 20 Å or less. In some embodiments, the thin selective layer of the nano-hybrid TFC CMS membranes comprises micropores with an average size in the range of about 7 Å to about 20 Å, and further comprises ultramicropores with an average size in the range of about 7 Å or less. The distribution of micropores and ultramicropores can be advantageous as the larger micropores can provide a low diffusion resistance pathway for bulk gaseous species, whereas the volume fraction with smaller micropores (e.g., ultramicropores) can provide the molecular sieving effect for discriminating against gas molecules based on size.

At least one benefit of the nano-hybrid TFC CMS membranes is that the separation performance of the membranes is at least similar or superior to the separation performance of CMS membranes pyrolyzed at high temperatures, such as above 700° C., or even 800° C. or higher. To achieve the same performance metrics without the need for treatment at extremely high temperatures, molecularly dispersed metal oxides are introduced and dispersed throughout the carbon matrix to tighten the microporosity. The ability to fabricate nano-hybrid TFC CMS membranes without such high temperatures provides an opportunity to utilize a much greater array or variety of supports or substrates. In other words, substrates that would otherwise fail—either physically, mechanically, chemically, or otherwise—under high temperatures (e.g., temperatures of at least about 700° C.) can now be employed as supports for the nano-hybrid TFC CMS membranes disclosed herein. Any of the supports of the present disclosure can be utilized herein.

Physical aging of membranes generally refers to the natural densification of an amorphous structure that can lead to dramatic losses in permeability. While there are some conventional membranes (i.e., those with thicknesses above 10 micrometers, and thin films with thicknesses between 1 to 5 microns) that exhibit increases in selectivity over time, conventional membranes typically exhibit losses in permeability and no change or substantially no change in selectivity over time. Conversely, the nano-hybrid TFC CMS membranes disclosed herein unexpectedly exhibit a unique physical aging signature in which, although the permeability losses may be similar to the rates observed in conventional membranes, the selectivity of the nano-hybrid TFC CMS membranes unexpectedly increases with time. For example, in some embodiments, nano-hybrid TFC CMS membranes with 1 micrometer thickness or greater can gain selectivity with time; whereas, in some embodiments, nano-hybrid TFC CMS membranes with thicknesses reduced significantly below 1 micrometer (e.g., 200 nm) may lose permeability without gaining selectivity. In some embodiments, the nano-hybrid TFC CMS membranes exhibit significant increases in selectivities over time, even up to about 2 months. For example, the selectivity of the nano-hybrid TFC CMS membranes with physical aging can increase at least about 1 time, 2 times, 3 times, or 4 times or greater.

The thickness of the thin selective layer is not particularly limited. In general, the thickness of the thin selective layer can be at least about 0.01 microns, preferably at least about 0.1 microns or greater, e.g., up to about 1 mm In certain embodiments, the thickness of the thin selective layer can be no more than about 1 micron, no more than about 900 nm, no more than about 800 nm, no more than about 700 nm, no more than about 600 nm, no more than about 500 nm, no more than about 400 nm, no more than about 300 nm, no more than about 250 nm, no more than about 200 nm, no more than about 175 nm, no more than about 150 nm, no more than about 125 nm, no more than about 100 nm, no more than about 75 nm, no more than about 50 nm, no more than about 25, or any increment or value thereof. In certain embodiments, the thickness of the thin selective layer is in the range of about 1 micron to about 1.5 microns. In certain embodiments, the thickness of the thin selective layer is less than about 5 microns. In certain embodiments, the thickness of the thin selective layer is less than about 2 microns. In certain embodiments, the thickness of the thin selective layer is less than about 1.5 microns. Similarly, the thickness of the optional substrate and protective layer are not particularly limited and can generally be in the range of at least about 0.01 microns or greater.

### APPLICATIONS OF THIN FILM COMPOSITE CARBON MOLECULAR SIEVE MEMBRANES

Methods of separating one or more chemical species using any of the thin film composite carbon molecular sieve membranes of the present disclosure are further disclosed herein. Examples of applications in which the nano-hybrid thin film composite carbon molecular sieve membranes can be used include, but are not limited to, separating oxygen and/or nitrogen from air, CO2 capture from flue gas, propane/propene separation, hydrogen purification, hydrogen recovery from refinery fuel gas and exhaust gas, methane enrichment, acid gas removal from natural gas, dehydration processes, and the like. In some embodiments, the nano-hybrid TFC CMS membranes are used for the separation of specific gases including, but not limited to, CO₂ and CH₄, H₂S and CH₄, CO₂ and H₂S and CH₄, CO₂ and N₂, O₂ and N₂, N₂ and CH₄, He and CH₄, H₂ and CH₄, H₂ and C₂H₄, ethylene and ethane, propylene and propane, ethylene/propylene, and ethane/propane, among others.

FIG. 1B is a flowchart of a method of separating one or more chemical species, according to one or more embodiments of the present disclosure. The method 100B can proceed by contacting 101B the thin film composite carbon molecular sieve membranes disclosed herein with a fluid composition and separating at least one chemical species from the fluid composition. The contacting can proceed by feeding, flowing, passing, injecting, or introducing the fluid composition to the thin film composite carbon molecular sieve membrane. The fluid compositions can include at least one chemical species, two or more chemical species, three or more chemical species, and so on. In some embodiments, for example, the fluid composition comprises chemical species including one or more of CO₂, CH₄, H₂S, CO, O₂, N₂, H₂, He, and C1+ hydrocarbons (e.g., ethane, ethylene, propylene, propane, propene, butane, iso-butane, iso-butylene, butadiene, pentanes, hexanes, xylenes, etc.), among others. These shall not be limiting, as other chemical species can be included in the fluid composition without departing from the scope of the present disclosure.

The at least one chemical species of the fluid composition can be separated 102B from a bulk or from a specific chemical species or group thereof. In some embodiments, the separating can result in the production of a retentate stream having a reduced concentration of at least one species and a permeate stream having an increased concentration of that species. In certain embodiments, the thin film composite carbon molecular sieve membranes can be utilized to separate CO₂ from CH₄. In certain embodiments, the thin film composite carbon molecular sieve membranes can be utilized to separate O₂ from N₂. In certain embodiments, the thin film composite carbon molecular sieve membranes can be utilized to separate H₂ from N₂. In certain embodiments, the thin film composite carbon molecular sieve membranes can be utilized to separate CO₂ and CH₄. In certain embodiments, the thin film composite carbon molecular sieve membranes can be utilized to separate H₂S and CH₄. In certain embodiments, the thin film composite carbon molecular sieve membranes can be utilized to separate CO₂ and H₂S and CH₄. In certain embodiments, the thin film composite carbon molecular sieve membranes can be utilized to separate CO₂ and N₂. In certain embodiments, the thin film composite carbon molecular sieve membranes can be utilized to separate O₂ and N₂. In certain embodiments, the thin film composite carbon molecular sieve membranes can be utilized to separate N₂ and CH₄. In certain embodiments, the thin film composite carbon molecular sieve membranes can be utilized to separate He and CH₄. In certain embodiments, the thin film composite carbon molecular sieve membranes can be utilized to separate H₂ and CH₄. In certain embodiments, the thin film composite carbon molecular sieve membranes can be utilized to separate H₂ and C₂H₄. In certain embodiments, the thin film composite carbon molecular sieve membranes can be utilized to separate ethylene and ethane. In certain embodiments, the thin film composite carbon molecular sieve membranes can be utilized to separate propylene and propane. In certain embodiments, the thin film composite carbon molecular sieve membranes can be utilized to separate ethylene and propylene. In certain embodiments, the thin film composite carbon molecular sieve membranes can be utilized to separate ethane and propane. In certain embodiments, the thin film composite carbon molecular sieve membranes can be utilized to separate n-butane from iso-butane. In certain embodiments, the thin film composite carbon molecular sieve membranes can be utilized to separate iso-butylene from iso-butane. In certain embodiments, the thin film composite carbon molecular sieve membranes can be utilized to separate pentane, hexane, and/or xylene isomers.

The following Examples are intended to illustrate the above invention and should not be construed as to narrow its scope. One skilled in the art will readily recognize that the Examiners suggest many other ways in which the invention could be practiced. It should be understood that numerous variations and modifications may be made while remaining within the scope of the invention.

### EXAMPLE 1

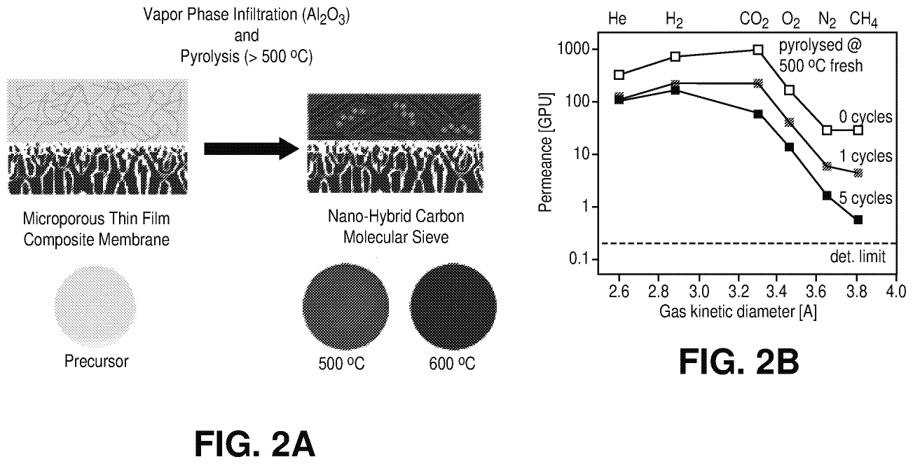

The following Example presents a new method to fabricate nano-hybrid CMS thin film composite membranes with microporosity fine-tuned on a molecular level by a dispersion of inorganic Al₂O₃ within the carbon matrix. The membranes were fabricated by a method with general applicability that involves vapor phase infiltration (VPI) of the thin film PIM precursor with a metal-containing or metal-organic precursors, such as Al-containing compound (trimethylaluminum, TMA), followed by oxidation with water vapor and, eventually, pyrolysis. The resulting nano-hybrid CMS membranes exhibited excellent separation properties typical to high temperature carbons except the resulting members were formed at moderate pyrolysis temperatures. The result is to simplify the choice of a suitable CMS membrane support for practical applications. Moreover, the physical aging characteristics of the obtained membranes were shown to be distinct from the typical fast loss of permeance with largely preserved selectivity typical to un-doped CMS thin films. The VPI-derived nano-hybrid CMS membranes, in contrast, seemed to gain selectivity with aging up to 2 months after fabrication. Given a very large spectrum of available metalorganic VPI precursors, as well as broad possibilities to optimize the doping process, it is believed that the presented method shows a tremendous potential both for a precise fine-tuning of the membrane properties and for upscaling. See, for example, FIGS. 2A-2B which shown a (A) schematic drawing of the methods disclosed herein (B) with a graphical view of permeance, according to one or more embodiments of the present disclosure.

### Experimental Methods

### Membrane Fabrication

The CMS polymer precursor, SBFDA-DMN, was synthesized by a polymerization of spirobifluorene-based dianhydride with 3,3′ dimethylnaphtihidine. The polymer possessed molecular weight Mₙ=6.5·10⁴ g mol⁻¹ with a polydispersity of about 1.92 and an internal surface area S_{BET}=686 m² g⁻¹. The decomposition onset was determined by TGA at ˜520° C. The polymer combined a PIM character (high internal surface area and a rigid backbone) with a very high aromatic carbon content (about 84 wt. %) which was proved to result in high quality carbon molecular sieves membranes following pyrolysis.

Thin film composite membranes were fabricated by a deposition of about 50 μL of ˜1 wt. % SBFDA-DMN solution in chloroform on top of AAO (Whatman Anodisc™, Sigma Aldrich) with about 20 nm surface pores. This resulted in an approximately 1-1.5 micron layer thickness as measured with spectroscopic ellipsometry on five spots on the surface. The sufficiently small surface pores of the AAO substrates assured virtually no pore intrusion by the coating solution and resulted in a sharp, well-defined support-thin film interface. For the XPS, SIMS, Spectroscopic Ellipsometry, AFM and optical imaging an additional set of samples were fabricated by spin-coating ˜3 wt. % polymer precursor solution on top of silicon wafers with about 500 nm thermally grown silicon oxide. The resulting SBFDA-DMN films were about 300 nm thick.

### Membrane Modification by Vapor Phase Infiltration (VPI)

A commercial Atomic Layer Deposition system (Cambridge Nanotech, model Savannah S100) was used to perform the Vapor Phase Infiltration (VPI) of the precursor polymer by using Trimethylaluminum (TMA) as VPI precursor followed by a subsequent oxidation with deionized water (vapor). The deposition was carried out at about 200° C. with a constant N₂ flow rate of about 15 sccm at about 0.2 Torr pressure. The infiltration was accomplished by isolating the ALD chamber from the pumping line and pulsing the precursor or water (about 15 ms pulse duration) followed by about 10 s exposure before purging the chamber again. Exposure to TMA with a subsequent exposure to water vapor constituted 1 cycle. In this work, 1, 5 and 20 cycles were used to modify the polymer precursor. Control samples (0 cycles) underwent exactly the same heating protocol as VPI-modified samples without, however, exposure to either of the reactants.

### Membrane Characterization

Multiple characterization techniques were used to extensively characterize the fabricated hybrid samples. X-Ray Photoelectron Spectroscopy (XPS) analysis was performed on a Kratos Axis Ultra DLD instrument equipped with a monochromatic Al K_{α} X-ray source (hv=1486.6 eV) operated at 120 W under UHV conditions (−10 mbar). The spectra were recorded in a hybrid mode using electrostatic and magnetic lenses and an aperture slot of 300 by 700 μm. The survey and high-resolution spectra were acquired at fixed analyzer pass energies of 160 eV and 20 eV, respectively. The samples were mounted in a floating mode to avoid differential charging. The spectra were acquired under charge neutralization conditions.

Atomic Force Microscopy (AFM) was performed using a TESPA probe in a tapping mode with the Dimension ICON instrument. About 1 μm² areas were analyzed on all pristine, hybrid and pyrolyzed samples on Si wafer-deposited films. The optical microscope of the AFM device was used to take optical images of all samples under identical illumination conditions.

### Secondary Ion Mass Spectroscopy (SIMS).

Dynamic secondary ion mass spectrometry (SIMS) was done using a Hiden instrument (Warrington, UK) operated under ultra-high vacuum conditions (typically about 10⁻⁹ Torr). A continuous Ar⁺ beam was employed at 4 keV to sputter the sample surface while the selected ions were sequentially collected using a MAXIM spectrometer equipped with a quadrupole analyzer. The raster of the sputtered area was approximately 750×750 μm. To avoid the edge effect during depth profiling, data were recorded from a small area located in the middle of the eroded region. The acquisition area was adjusted using adequate electronic gating to about 75×75 μm. A conversion of the sputtering time to sputtering depth was carried out assuming a constant sputtering rate and accounting for the measurement of the crater depth with a stylus profiler from Veeco.

### Spectroscopic Ellipsometry

Spectroscopic Ellipsometry (SE) was used to determine the thickness of the precursor membranes deposited on the AAO substrates, as well as the thickness and optical properties of the Si wafer deposited samples. This approach has been previously demonstrated for studies on similar composite membrane systems. SE was conducted using M-2000 DI instrument from J. A. Woollam Co., Inc. equipped with focusing optics (300 μm short axis) in a wavelength range of about 192-1700 nm at five angles of incidence (about 55, about 60, about 65, about 70 and about 75° . The analysis process was similar to other studies and involved utilization of either Cauchy model in a range of about 500-1700 nm (with included Urbach tail to handle the light absorption) or B-Spline model in a full spectral range. Effective Medium Approximation theory (EMA) was used to extract the volume fractions of Al₂O₃ within the polymer film by assuming molecular level inclusion of the inorganic domains into the organic polymer thereby satisfying the EMA assumptions. The pristine polymer dielectric function was first fitted using the B-Spline to serve as the first component in the EMA mixture. The optical properties of the second component, Al₂O₃, were taken from a literature database. A 15-layer graded optical dispersion was used to approximately determine the distribution of the Al₂O₃ within the interface of the hybrid films to mimic the SIMS-derived data.

### Results and Discussion

Vapor Phase Infiltration (VPI) to create organic-inorganic hybrids has only recently been described to enhance the mechanical properties of spider silk. However, the field is currently undergoing a very rapid development. Numerous application areas are expected to benefit from a more widespread use of this relatively novel technique, such as improvement of mechanical properties of common polymers (polyolefins, polystyrene, polyamides, and block copolymers), sorbents, optics, lithography, or electronics etc. To date, however, VPI has not been utilized in microporous membranes, neither was it applied in combination with ultra-high free volume materials such as polymers of intrinsic microporosity (PIMs) or in combination with high temperature treatment (pyrolysis). Only one report exists on attempting to fabricate ceramic porous membranes for solvent filtration with much larger pores (˜10 nm) by using infiltrated block copolymers as templates. In contrast to those membranes, PIMs represent intrinsically microporous (pores<2 nm) membrane materials where the inefficient packing, being a result of an extremely rigid and contorted backbones of PIMs, allows trapping very high amounts of excess fractional free volume or microporosity. As a result, PIMs exhibit extremely attractive gas separation properties.

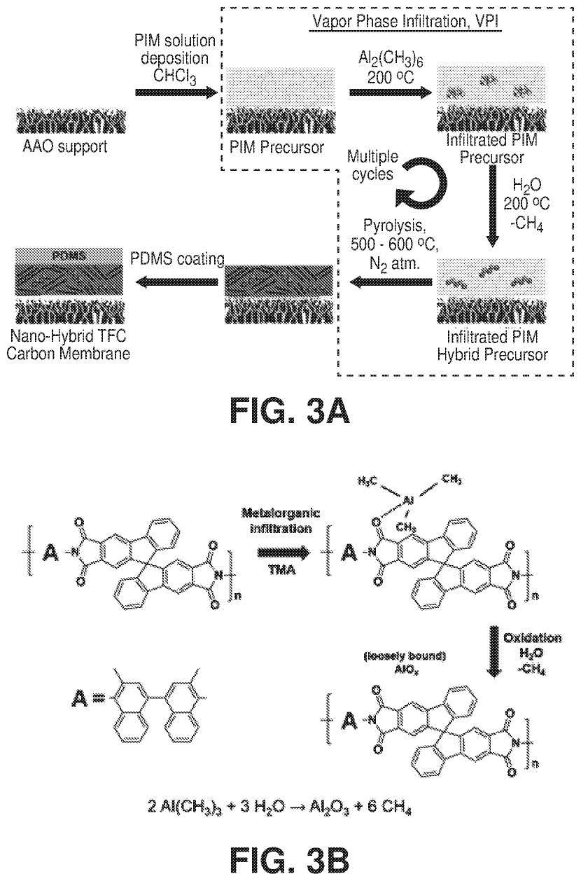

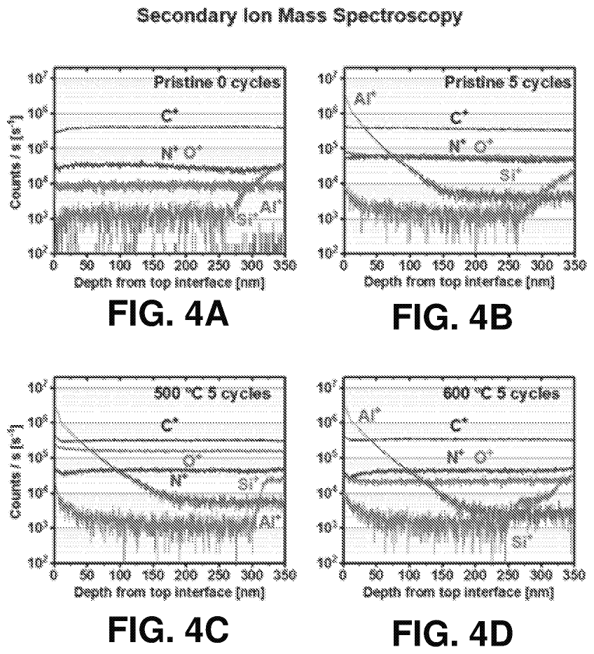

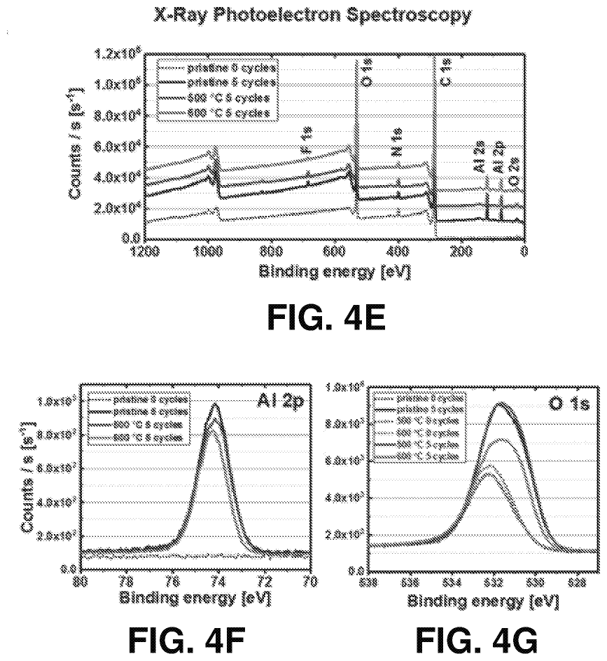

FIG. 3A shows a scheme of the VPI process applied directly to a thin film carbon molecular sieve (CMS) PIM precursor film followed by inert atmosphere pyrolysis and protective thin film PDMS deposition. The VPI process itself was and can be repeated multiple times thereby allowing for a precise tuning of the resulting aluminum oxide volume fraction (as determined by spectroscopic ellipsometry and XPS). Trimethylaluminum (TMA) was suggested to form a reversible complex with the functional groups of the polymer matrix (imide groups in the case of our PIM), FIG. 3B. Simultaneously, the high microporosity of the polymer facilitated efficient diffusion of TMA deep into the interface of the membrane selective layer. These large penetration depths are uncommon in low free volume standard polymers (e.g. polyolefins or polyamids) where, in contrast, a thin dense layer of Al₂O₃ tends to form at the top interface. The significant depth of penetration was confirmed by the Secondary Ion Mass Spectroscopy data, FIGS. 4A-4D, where in the case of infiltrated samples, the Al ion signal persisted up to depths of about 150 nm. Additionally, the Al ion signal showed almost no variation upon subsequent high temperature (about 500 and about 600° C.) pyrolysis. The easy tunability of the Al₂O₃ volume fraction was demonstrated in additional SIMS diagrams where its intensity increased with increasing number of VPI cycles. Optical images of the pristine polymer samples, as well as the pyrolyzed and non-pyrolyzed hybrids showed no changes to the top film surface. AFM confirmed a very low surface roughness (RMS<0.5 nm) with a slight increase for the hybrid sample pyrolyzed at about 500° C.

XPS data, presented in FIGS. 4E-4G, strongly suggested that the Al element was efficiently incorporated at a weight fraction of about 7.7% after just 5 VPI cycles and remained in the structure following the pyrolysis. The peak shape analysis for Al 2 p peaks, FIGS. 4E-4G, indicated that Al existed within the structure only as aluminum oxide (a shift from 72.6 eV for oxidation state of 0 to around 74.6 eV in Al₂O₃) and remained rather loosely (physically) bound to the polymer chains. This observation was in agreement with extensive previous studies and seemed to be a general feature of the VPI in most typical cases e.g. deposition of Al₂O₃, ZnO or TiO₂. With respect to O 1 s peak, clearly a second contribution from Al₂O₃ next to the one from the preexisting carbonyl group of the pristine polymer developed upon 5 cycles of VPI and remained present upon pyrolysis.

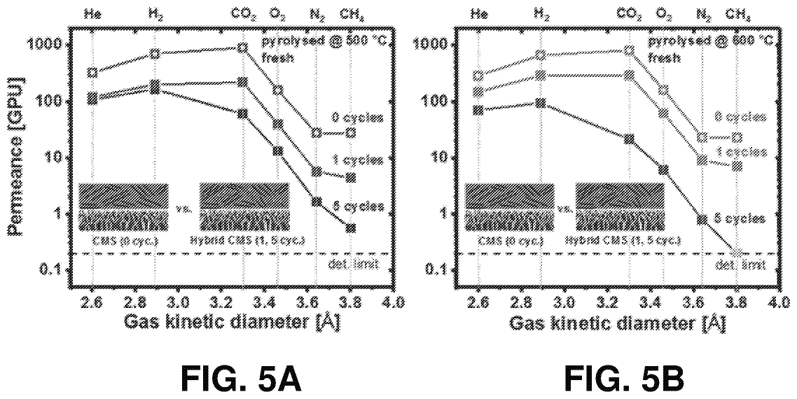

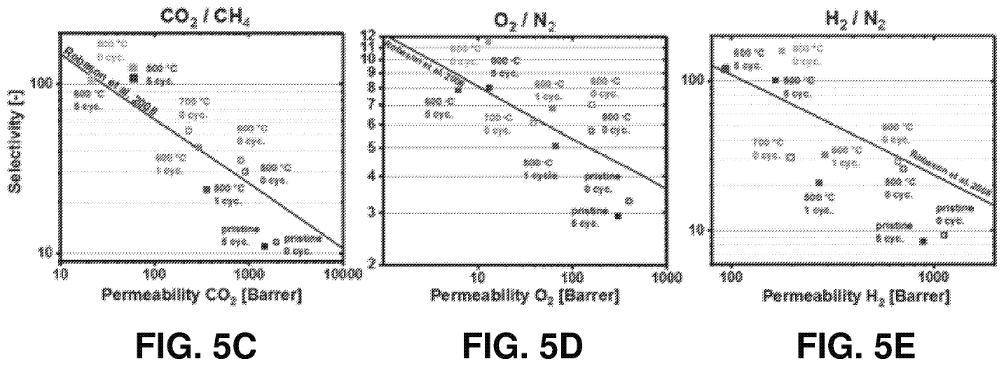

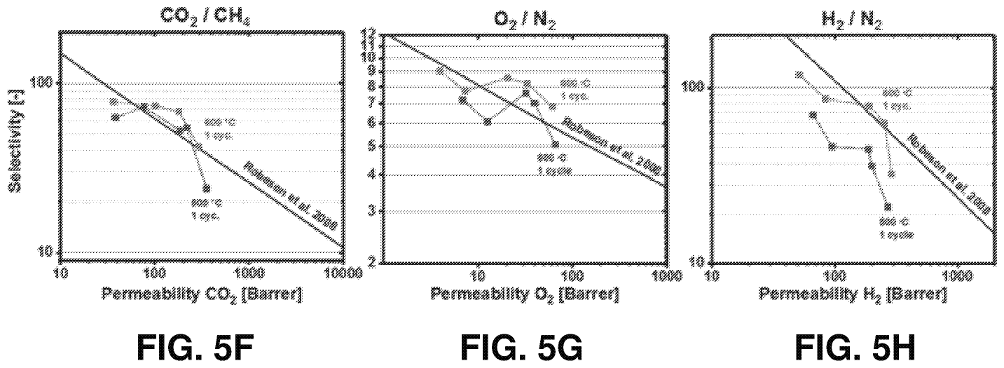

Following the VPI and pyrolysis, the AAO-supported nano-hybrid CMS membranes were tested with respect to their ideal gas separation performance In FIGS. 5A-5E, data for freshly made samples (aged for about 1 day) are presented while the entire physical aging trajectories up to 60 days are shown in FIGS. 5F-5H. Remarkably, the VPI process led to a strong enhancement of the molecular sieving character of the pyrolyzed membranes, FIGS. 5A-5B. The unmodified CMS membranes (denoted as “0 cycles”) exhibited some solubility contribution of the more condensable CO₂ and H₂ (as expected from the solution diffusion mechanism) and, therefore, these two gases were faster than the significantly smaller He. After just 1 VPI cycle the character started to change and by 5 VPI cycles the membranes displayed a very strong molecular sieving effect with the permeances closely following the molecular size of the gas molecules. Simultaneously, permeances of all gases reduced very significantly. In particular, for the 5 VPI cycles sample pyrolyzed at 600° C. a very strong sieving was revealed by a drastically reduced (to below detection limit) permeance of the largest methane.

Membrane performance is often benchmark by using the so-called Robeson diagrams that plot membrane selectivity for a particular gas pair versus permeability of the faster component. The existence of the trade-offs, originally for purely polymeric membranes, has been well documented both experimentally and theoretically, and indicates a general inability of amorphous polymer materials to afford both high selectivity and permeability. Unmodified carbon molecular sieves have been shown to, in many instances, overcome the trade-offs especially when measured as thick isotropic films. FIGS. 5C-5E shows the performance of thin film composite membranes of the present Example calculated based on the permeability of the selective membrane layer from the resistances in series model. This required the knowledge of the selective layer membrane thickness as well as the protective PDMS layer which also contributed to transport resistance albeit to a minor extent. Both thicknesses were provided with Spectroscopic Ellipsometry analysis, and were about 1-1.5 and about 0.6-0.9 micron for the CMS and PDMS layers, respectively. All fabricated membranes presented excellent separation performance combining very high selectivities and permeabilities and positioned themselves near or above the trade-off lines. FIGS. 5C-5E also depicts the performance of unmodified membranes pyrolyzed at much higher temperatures (up to about 800° C.) taken from previous work of Applicants. It was clear that increasing the number of VPI cycles shifted the molecular sieving performance towards that of unmodified CMS membranes pyrolyzed at much higher temperatures. For instance, a nano-hybrid CMS membrane pyrolyzed at 500° C. subjected to 5 VPI cycles performed very similarly to an unmodified CMS membrane pyrolyzed at about 800° C. This remarkable finding suggested that the introduction of the molecularly dispersed Al₂O₃ was able to tighten the microporosity essentially mimicking the very strong sieving capabilities of extremely dense, high-temperature CMS membranes without the need for extremely high treatment temperatures. This feature may present very significant practical advantages by extending the spectrum of available CMS membrane supports to those less heat resistant. In addition, the risk of mechanical damage because of the thermal stress, like pore collapse in all-polymer fibers or cracking, could be greatly reduced. Lastly, avoiding very high pyrolysis temperatures may have obvious practical implications in terms of membrane fabrication complexity and cost.

The physical aging process tracked up to 60 days for the nano-hybrid CMS membranes is shown in FIGS. 5F-5H. As mentioned earlier, physical aging presented a considerable challenge especially in thin film composite membranes where the natural densification of the amorphous structure led to dramatic losses of permeability. Yet, physical aging behavior has very rarely been reported especially in studies dealing with thin-skinned CMS membranes. It was established that indeed thin film CMS membranes tend to rapidly densify with time and that reduction of film thickness has a dramatic effect on the permeability but exerts a very small influence on the selectivity. This was explained by a predominant collapse of the larger micropores in the range roughly 7-20 Å. For ˜1 micron thick unmodified CMS membranes 30 days of aging under ambient conditions resulted in a 3-5 fold reduction of permeability with almost no change in selectivity. In this context, the physical aging behavior of the nano-hybrid CMS membranes appeared significantly different. In the case of three of the most technologically important gas pairs, CO₂/CH₄, O₂/N₂ and H₂/N₂, physical aging seemed to largely follow the tradeoff lines. As a result, the loss of permeabilities (which occurred at a similar rate as in the unmodified membranes) was accompanied by significant increases in the selectivities even up to ˜2 months of aging.

Tables 1 and 2 summarize performance data for the thin film CMS membranes. In particular, Table 1 summarizes the permeances and ideal selectivities of freshly fabricated (1 day aged) nano-hybrid and control (un-doped) carbon molecular sieve membranes. Table 2 summarizes permeances and ideal selectivities of aged nano-hybrid and control (un-doped) carbon molecular sieve membranes.

TABLE 1
Permeances and Ideal Selectivities of Freshly Fabricated (1 day aged)
Nano-Hybrid and Control (Un-doped) Carbon Molecular Sieve Membranes.

| | Permeance [GPU] | | | | | | Ideal Selectivity [—] | | |
|---|---|---|---|---|---|---|---|---|---|
| Membrane | He | H₂ | N₂ | O₂ | CH₄ | CO₂ | O₂/N₂ | CO₂/CH₄ | H₂/N₂ |
| Pristine 0 cycles | 420 | 1127 | 120 | 396 | 168 | 1948 | 3.3 | 11.6 | 9.4 |
| Pristine 5 cycles | 378 | 882 | 104 | 303 | 133 | 1461 | 2.9 | 11.0 | 8.5 |
| 500° C. 0 cycles | 324 | 707 | 27.4 | 159 | 27.6 | 907 | 5.7 | 30.3 | 25.8 |
| 600° C. 0 cycle | 288 | 665 | 22.9 | 161 | 23.1 | 813 | 7.0 | 35.3 | 28.9 |
| 700° C. 0 cycle | 70 | 196 | 6.4 | 38.7 | 4.3 | 228 | 6.1 | 53.0 | 30.8 |
| 800° C. 0 cycle | 96.2 | 178 | 1.1 | 12.9 | 0.47 | 58.3 | 11.5 | 124 | 159 |
| 500° C. 1 cycle | 146 | 271 | 13.0 | 65.8 | 15.0 | 356 | 5.1 | 23.8 | 20.9 |
| 600° C. 1 cycle | 150 | 290 | 9.0 | 61.4 | 6.9 | 291 | 6.8 | 41.9 | 32.2 |
| 500° C. 5 cycles | 107 | 165 | 1.6 | 13.1 | 0.56 | 59.9 | 8.0 | 108 | 101 |
| 600° C. 5 cycles | 70.2 | 93.5 | 0.8 | 6.2 | 0.2 | 21.2 | 7.9 | 106 | 120 |

TABLE 2
Permeances and Ideal Selectivities of Aged Nano-Hybrid and
Control (Un-doped) Carbon Molecular Sieve Membranes.

| | Permeance [GPU] | | | | | | Ideal Selectivity [—] | | |
|---|---|---|---|---|---|---|---|---|---|
| Membrane | He | H₂ | N₂ | O₂ | CH₄ | CO₂ | O₂/N₂ | CO₂/CH₄ | H₂/N₂ |
| 500° C. 0 cycle* | 94.0 | 193.3 | 12.1 | 51.1 | 9.2 | 278.0 | 4.2 | 30.2 | 16.0 |
| (30 days aged) | | | | | | | | | |
| 600° C. 0 cycle* | 119.0 | 254.3 | 12.6 | 79.1 | 10.9 | 402.7 | 6.3 | 36.9 | 20.1 |
| (30 days aged) | | | | | | | | | |
| 500° C. 1 cycle | 57.4 | 95.0 | 2.1 | 12.6 | 1.1 | 76.5 | 6.0 | 69.5 | 45.2 |
| (30 days aged) | | | | | | | | | |
| 600° C. 1 cycle | 33.5 | 83.9 | 0.95 | 7.4 | 0.46 | 36.2 | 7.8 | 78.7 | 88.3 |
| (30 days aged) | | | | | | | | | |
| 500° C. 1 cycle | 39.7 | 66.8 | 0.95 | 6.9 | 0.62 | 38.1 | 7.2 | 62.6 | 69.9 |
| (60 days aged) | | | | | | | | | |
| 600° C. 1 cycle | 31.4 | 51.7 | 0.43 | 4.0 | (—) | 16.8 | 9.1 | >85 | 118.3 |
| (60 days aged) | | | | | | | | | |

(—) below detection limits;
*data from our earlier study [30]

Finally, it was noted that the VPI process itself builds on the extensive experience of the vapor deposition community (in particular, ALD) and presents a very wide tunability with a multitude of organometallic precursors available (trimethylaluminum, diethyl zinc, titanium tetrachloride etc.), multiple deposition sequences (continuous, semi-static, pulsed depositions) or protocols (contacting time of the organometallic precursor with the polymer matrix). This led to very attractive optimization possibilities to further fine-tune the separation properties as well as the long-term performance of hybrid, organic-inorganic thin film composite membranes. These possibilities are not necessarily limited to approaches relying on a subsequent pyrolysis and fabrication of CMS-type membranes. Furthermore, because of its in-situ nature it was further envision a possibility to modify the as-fabricated composite membranes (either flat sheet or hollow fibers) by exposing them to the organometallic precursor and an oxidant already inside the module. This would present an attractive membrane modification strategy with a minimal impact on the entire process of membrane system fabrication. VPI-derived introduction of specific catalytic functionalities provided by some heavy metal atoms (like Pd) might represent another possibility for novel hybrid properties.

In summary, nano-hybrid thin film composite carbon molecular sieve (CMS) membranes are introduce by combining vapor phase infiltration (VPI) with high temperature pyrolytic collapse of organic polymer matrix. While in this work Al₂O₃ was used, VPI allows for a molecular level dispersion of a wide range of metal oxides and a high tunability of the process by building on the extensive experience of the vapor deposition community. The synthesized nano-hybrid CMS membranes showed excellent gas separation performance and positioned themselves near or above state of the art polymeric membranes. VPI enables obtaining very high gas pair selectivities typical to high temperature CMS membranes at, however, temperatures lower by about 200-300° C. This may have significant practical applications for the scale up by enabling a much wider spectrum of available CMS supports and alleviating some of the challenges related with very high pyrolysis temperatures such as membrane mechanical stability and fabrication complexity.

Other embodiments of the present disclosure are possible. Although the description above contains much specificity, these should not be construed as limiting the scope of the disclosure, but as merely providing illustrations of some of the presently preferred embodiments of this disclosure. It is also contemplated that various combinations or sub-combinations of the specific features and aspects of the embodiments may be made and still fall within the scope of this disclosure. It should be understood that various features and aspects of the disclosed embodiments can be combined with or substituted for one another in order to form various embodiments. Thus, it is intended that the scope of at least some of the present disclosure should not be limited by the particular disclosed embodiments described above.

Thus the scope of this disclosure should be determined by the appended claims and their legal equivalents. Therefore, it will be appreciated that the scope of the present disclosure fully encompasses other embodiments which may become obvious to those skilled in the art, and that the scope of the present disclosure is accordingly to be limited by nothing other than the appended claims, in which reference to an element in the singular is not intended to mean “one and only one” unless explicitly so stated, but rather “one or more.” All structural, chemical, and functional equivalents to the elements of the above-described preferred embodiment that are known to those of ordinary skill in the art are expressly incorporated herein by reference and are intended to be encompassed by the present claims. Moreover, it is not necessary for a device or method to address each and every problem sought to be solved by the present disclosure, for it to be encompassed by the present claims. Furthermore, no element, component, or method step in the present disclosure is intended to be dedicated to the public regardless of whether the element, component, or method step is explicitly recited in the claims.

The foregoing description of various preferred embodiments of the disclosure have been presented for purposes of illustration and description. It is not intended to be exhaustive or to limit the disclosure to the precise embodiments, and obviously many modifications and variations are possible in light of the above teaching. The example embodiments, as described above, were chosen and described in order to best explain the principles of the disclosure and its practical application to thereby enable others skilled in the art to best utilize the disclosure in various embodiments and with various modifications as are suited to the particular use contemplated. It is intended that the scope of the disclosure be defined by the claims appended hereto

Various examples have been described. These and other examples are within the scope of the following claims.

1. A method of fabricating a thin film composite carbon molecular sieve membrane, the method comprising:
(a) exposing a polymer layer to a vapor-phase metal-organic precursor under vapor phase infiltration conditions, wherein the vapor-phase metal-organic precursor diffuses into the polymer layer and reacts with a functional group of the polymer to form an inorganic-organic complex;
(b) exposing the polymer layer to a vapor-phase co-reactant under vapor phase infiltration conditions, wherein the vapor-phase co-reactant diffuses into the polymer layer and oxidizes the organic-inorganic complex to form a metal oxide; and
(c) subjecting the polymer layer to inert-atmosphere or vacuum pyrolysis; wherein the polymer layer comprises a polymer of intrinsic microporosity.

2. The method according to claim 1, wherein the polymer layer comprises a polymer of intrinsic microporosity includes an average pore size of about 2 nm or less.

3. (canceled)

4. The method according to claim 1, wherein the functional group comprises a nitrogen atom, oxygen atom, phosphorus atom, sulfur atom, or halogen.

5. The method according to claim 1, wherein the metal-containing precursor is selected from the group consisting of trimethylaluminum, diethyl zinc, titanium tetrachloride, triethylaluminum, titanium isopropoxide, zinc oxide, zinc chloride, zirconium tetrachloride, titanium oxide, aluminum trichloride, tungsten hexafluoride, silane, molybdenum fluoride, tetraethylorthosilicate, dimethylchloro aluminum, methyldichloro aluminum, metal alkyls, metal tetrakisalkylamidos, metal cyclopentadienyls, or metal diketonates.

6. The method according to claim 1, wherein the co-reactant is water.

7. The method according to claim 1, wherein the metal oxide comprises a metal selected from the group consisting of transition metals, post-transition metals, lanthanoids, actinoids, alkali metals, or alkaline earth metals.

8. The method according to claim 1, wherein steps (a) and (b) are performed one or more times.

9. The method according to claim 1, wherein the pyrolysis temperature is less than 700° C.

10. The method according to claim 1, wherein the pyrolysis temperature is less than 600° C.

11. A hybrid metal oxide-carbon molecular sieve thin film composite membrane fabricated according to the method of claim 1.

12. The membrane according to claim 1, wherein the membrane comprises a thin selective layer supported on a substrate, wherein the thin selective layer comprises a metal oxide dispersed throughout a carbon matrix.

13. The membrane according to claim 1, wherein the membrane comprises micropores and ultramicropores.

14. The membrane according to claim 1, wherein the metal oxide comprises a molecular metal oxide.

15. The membrane according to claim 1, wherein the thickness of the thin selective layer is no more than about 5 microns.

16. The membrane according to claim 1, wherein the substrate comprises a heat sensitive material.

17. A method of separating chemical species, comprising:
contacting a thin film composite carbon molecular sieve membrane according to claim 1 with a fluid composition, and separating at least one chemical species from the fluid composition.

18. The method according to claim 17, wherein the fluid composition comprises one or more of CO₂, CH₄, H₂S, CO, O₂, N₂, H₂, He, and C1+ hydrocarbons.

19. The method according to claim 1, wherein the thin film composite carbon molecular sieve membrane separates CO₂ from CH₄, O₂ from N₂, or H₂ from N₂.

20. The membrane according to claim 1, wherein the selectivity of the membrane increases with time.

21. The method according to claim 1, wherein the polymer of intrinsic microporosity comprises an aromatic carbon content of about 65% to about 99%.

22. The method according to claim 1, wherein a penetration depth of the precursor is about 1% to about 100%.

23. The method according to claim 1, wherein a penetration depth of the precursor is about 150 nm.
